(19) United States
(12) Patent Application Publication
(10) Pub. No.: US 2015/0187978 A1
(43) Pub. Date: Jul. 2, 2015

(54) FLEXIBLE LIGHTING-PHOTOVOLTAIC COMPOSITE MODULE AND MANUFACTURING METHOD THEREOF

(71) Applicant: FLEXWAVE CO., LTD., Hsinchu City (TW)

(72) Inventors: Fang-Chung CHEN, Zhushan Township (TW); Chun-Hsien CHOU, Taichung City (TW)

(21) Appl. No.: 14/586,154

(22) Filed: Dec. 30, 2014

(30) Foreign Application Priority Data
Dec. 30, 2013 (TW) 102149094

(51) Int. Cl. H01L 31/054; H01L 31/048; H01L 25/16; H02S 40/38; H02S 40/30; H01L 25/00; H01L 31/055; H01L 31/0236

(52) U.S. Cl. CPC H01L 31/0543; H01L 31/055; H01L 31/0481; H01L 31/02366; H02S 40/38; H02S 40/30; H01L 25/50; H01L 25/167

(57) ABSTRACT

The present invention provides a flexible lighting-photovoltaic composite module and a manufacturing method thereof. The flexible lighting-photovoltaic composite module comprises: at least one light source; a photovoltaic module electrically connected with the light source and including at least one photovoltaic cell; and a flexible light guide element, wherein the light source is embedded in the flexible light guide element, and the photovoltaic module is embedded in the flexible light guide element or fixed on at least one side of the flexible light guide element to form the flexible lighting-photovoltaic composite module.

The present application claims priority to foreign patent application TW 102149094 filed on Dec. 30, 2013.

### BACKGROUND OF THE INVENTION

1. Field of the Invention

The present invention relates to a high flexibility and high plasticity lighting-photovoltaic composite module, particularly to a flexible lighting-photovoltaic composite module able to recycle light energy.

2. Description of the Prior Art

Fossil fuels are going to be exhausted by human beings, and combustion of fossil fuels generates waste gas polluting the environment. Solar batteries can directly convert solar energy into electric energy. Thus, they are regarded as an environment-protection substitute energy source and highly valued by the industry and concerned organizations.

Solar batteries are as called photovoltaic batteries. Under the global trend of energy saving and carbon reduction, many solar energy related products have emerged, such as solar energy street lamps and solar energy warning lights, wherein electric energy generated by solar energy modules in daylight is stored in batteries and released at night to power the illumination devices. Thus, energy is self-sustainable in these systems.

The commonly seen solar energy illumination systems are formed of solar energy modules and LED lights. However, these systems normally have the following disadvantages: 1. the conventional solar energy module has larger volume impairing the overall structural design thereof; 2. the conventional solar energy illumination system is bulky because the solar energy module and light sources are separated; 3. the application of the conventional solar energy module is limited because its frame is made of rigid materials, such as glass and aluminum; 4. the conventional solar energy module is expensive; 5. the conventional solar energy illumination system is inefficient in power generation and illumination because cloud and rain would reduce power storage and illumination duration; 6. the conventional solar energy illumination system is hard to have esthetic applications because it lacks diversified structures and rich colors.

The Inventor has been devoted to research for a long time and finally proposes a flexible lighting-photovoltaic composite module featuring high deformability, energy self-sustainability and low fabrication cost to promote application and popularization of solar energy illumination systems.

### SUMMARY OF THE INVENTION

One objective of the present invention is to provide a flexible lighting-photovoltaic composite module featuring high flexibility, high plasticity, and energy self-sustainability.

Another objective of the present invention is to provide a method for manufacturing a flexible lighting-photovoltaic composite module, which uses a low-temperature non-toxic process to manufacture an integrally molded flexible lighting-photovoltaic composite module.

To achieve the abovementioned objective, the present invention proposes a flexible lighting-photovoltaic composite module, which comprises at least one light source, a photovoltaic module and a flexible light guide element, wherein the photovoltaic module includes at least one photovoltaic cell, and wherein the light source and the photovoltaic module are embedded in the flexible light guide element, or independently disposed on at least one side of the flexible light guide element, or independently arranged in a combined way to form a flexible lighting-photovoltaic composite module.

In one embodiment, the light source is a conventional light source, such as LED (Light Emitting Diode) or OLED (Organic Light Emitting Diode). However, the present invention does not limit that the light source must be a special type of light source. In one embodiment, the photovoltaic module is a conventional solar energy module.

In the present invention, the flexible light guide element is a pliable light guide element, which can increase the rate of the light entering the photovoltaic module and the recycling efficiency of the light emitted by the light source. The flexible light guide element is made of a light guide material selected from a group consisting of PVA (polyvinyl alcohol), PVP (poly(vinylpyrrolidinone), and PDMS (polydimethylsiloxane). Preferably, the flexible light guide element is made of PDMS.

The flexible lighting-photovoltaic composite module further comprises a scattering layer disposed on at least one side of the flexible light guide element or embedded in the flexible light guide element.

In one embodiment, the scattering layer of the flexible lighting-photovoltaic composite module is disposed on one side of the flexible light guide element, and the light source is arranged on a first surface of the scattering layer and embedded in the flexible light guide element. The photovoltaic module is arranged on at least one side of the flexible light guide element.

In one embodiment, the scattering layer is embedded in the flexible light guide element, and the light source is further arranged on a second surface of the scattering layer.

In one embodiment, the photovoltaic module is embedded in the flexible light guide element. In one embodiment, the photovoltaic module penetrates the scattering layer or runs through the scattering transversely.

In one embodiment, the photovoltaic module comprises a plurality of the photovoltaic cells respectively disposed on at least two sides of the flexible light guide element. However, the present invention does not limit that the photovoltaic cells must be disposed on at least two sides of the flexible light guide element.

In one embodiment, the flexible lighting-photovoltaic composite module further comprises a pattern layer embedded in the flexible light guide element. The pattern layer is a physical pattern layer or a pattern layer whose text or patterns are fabricated with luminescent dyes. However, the present invention does not limit the number of the pattern layers. In some embodiments, the present invention comprises a plurality of pattern layers.

In one embodiment, a microstructure is transfer-printed on at least one surface of the flexible light guide element. The microstructure has micro cones, micro semispheres, micro cuboids, or a combination thereof. However, the present invention does not limit the shape of the microstructures.

In one embodiment, the surface of the flexible lighting-photovoltaic composite module is coated with a protection layer providing weather resistance and stain proof functions. The protection layer has a lower refractivity and is made of a material selected from a group consisting of ETFE (ethylene-tetra-fluoro-ethylene), ECTFE (ethylene-chlorotrifluororthylene), PTFE (polytetrafluoroethylene), FEP (fluorinated ethylene propylene), PET (polyethylene terephthalate), and PC (Polycarbonate). Preferably, the protection layer is made of ETFE. However, the present invention does not limit that the protection layer must be made of the abovementioned material.

The present invention also proposes a method for manufacturing a flexible lighting-photovoltaic composite module, which comprises
Step (a): electrically connecting a light source and a photovoltaic module and securing them in a mold, wherein the photovoltaic module includes at least one photovoltaic cell;
Step (b): pouring a light guide material solution into the mold and curing the light guide material solution to form a flexible light guide element, wherein the each of light source and the photovoltaic module is embedded in the flexible light guide element, disposed on at least one side of the flexible light guide element, or arranged in both ways; and
Step (c): removing the mold to obtain a flexible lighting-photovoltaic composite module.

In one embodiment, Step (b) is followed by Step (b1): embedding a pattern layer in the flexible light guide element.

In one embodiment, Step (b1) is followed by Step (b2): forming a scattering layer on at least one side of the flexible light guide element. Preferably, the scattering layer contains titanium dioxide, and the concentration of titanium dioxide is modified according to the required light transparency.

In one embodiment, Step (b2) is followed by Step (b3): pouring the light guide material solution on the scattering layer to embed the scattering layer in the flexible light guide element.

The light guide material solution contains a light guide material and a curing agent mixed by a ratio of 10 to 1:1. Preferably, the ratio is 10 to 2:1. More preferably, the ratio is 10:1. In one embodiment, the curing agent is a light curing agent or a thermal curing agent. However, the present invention does not limit that the curing agent must be a light curing agent or a thermal curing agent.

The structure of the flexible lighting-photovoltaic composite module manufactured by the method of the present invention is the same as that of the flexible lighting-photovoltaic composite module described above and will not repeat herein.

The flexible lighting-photovoltaic composite module is made of a light guide material featuring flexibility and light guidance, bendable into any desired curved surface, free of light shading, and able to be fabricated into an integral structure. Via using luminescent dyes or directly embedding pattern layers, the flexible lighting-photovoltaic composite module can present text or patterns and apply to advertisement boards, street lamps, and signboards. The light guide material of the flexible light guide element can conduct light and thus enable the flexible lighting-photovoltaic composite module to absorb more sunlight in the daytime and recycle the light emitted by the light source at night for power regeneration. Therefore, the present invention increases energy recycling efficiency, satisfies environment protection demands, and has advantages of low cost, esthetic appearance and diversified application.

### BRIEF DESCRIPTION OF THE DRAWINGS

FIG. 1 schematically shows the steps of a method for manufacturing a flexible lighting-photovoltaic composite module according to Embodiment I of the present invention;

FIG. 2 is a perspective view schematically showing a flexible lighting-photovoltaic composite module according to Embodiment II of the present invention;

FIG. 3 is a perspective view schematically showing a flexible lighting-photovoltaic composite module according to Embodiment III of the present invention;

FIG. 4 is a perspective view schematically showing a flexible lighting-photovoltaic composite module according to Embodiment IV of the present invention;

FIG. 5 is a perspective view schematically showing a flexible lighting-photovoltaic composite module according to Embodiment V of the present invention;

FIG. 6 shows a photograph of a flexible lighting-photovoltaic composite according to Embodiment VI of the present invention;

FIG. 7 shows a voltage-current relationship of the flexible lighting-photovoltaic composite shown in FIG. 6;

FIG. 8 shows a photograph of a flexible lighting-photovoltaic composite according to Embodiment VII of the present invention; and

FIG. 9 shows a voltage-current relationship of the flexible lighting-photovoltaic composite shown in FIG. 8.

### DESCRIPTION OF THE PREFERRED EMBODIMENT

Below, embodiments are used to demonstrate the present invention to enable the persons skilled in the art to understand the present invention. According to the specification, the persons skilled in the art should be able to modify or vary the embodiments easily without departing from the spirit of the present invention. Therefore, any modification or variation made according to the principle, characteristic or spirit of the present invention is to be also included within the scope of the present invention.

### Embodiment I

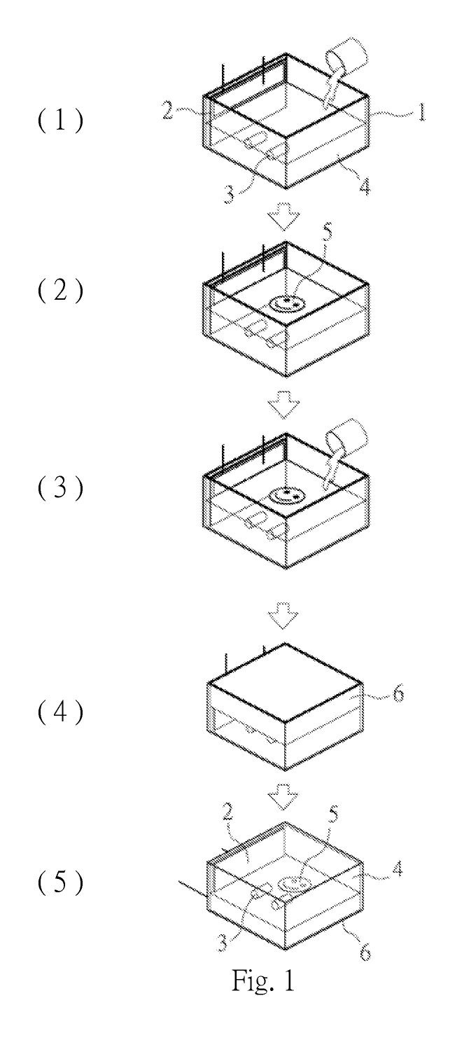

Refer to FIG. 1 a diagram schematically showing the steps of a method for manufacturing a flexible lighting-photovoltaic composite module according to Embodiment I of the present invention. In Step (1), electrically connect a photovoltaic module 2 with LED light sources 3 and fix them in a mold 1; mix a light guide material PDMS with a curing agent by a ratio of 10:1 to form a light guide material solution; agitate the light guide material solution uniformly and place it still for a period of time or place it in a vacuum chamber to remove air bubbles; pour the light guide material solution into the mold 1; and heat and cure the light guide material solution at a temperature of 90-120° to form a flexible light guide element 4. In this embodiment, the LED light sources 3 are embedded in the flexible light guide element 4, and the photovoltaic module 2 is fixed to one side of the flexible light guide element 4.

In Step (2), place a physical pattern layer 5 on the cured flexible light guide element 4. In Step (3), prepare a solution of titanium dioxide and PDMS mixed by a ratio of titanium dioxide:PDMS=0.2 g:1.8 ml, and add a curing agent to the solution by a ratio of PDMS:curing agent=10:1 to form a scattering solution; pour the scattering solution into the mold 1 to cover a physical pattern layer 5. The concentration of titanium dioxide can be modified according to the desired light transparency. In Step (4), heat and cure the scattering solution to form a scattering layer 6. In Step (5), keep heating until PDMS is completely cured; place the mold and the cured solution still until they are cooled down; remove the mold 1 to obtain the flexible lighting-photovoltaic composite module of the present invention.

If necessary, a light guide material is further formed over the scattering layer 6 to embed the scattering layer in the flexible light guide element 4.

### Embodiment II

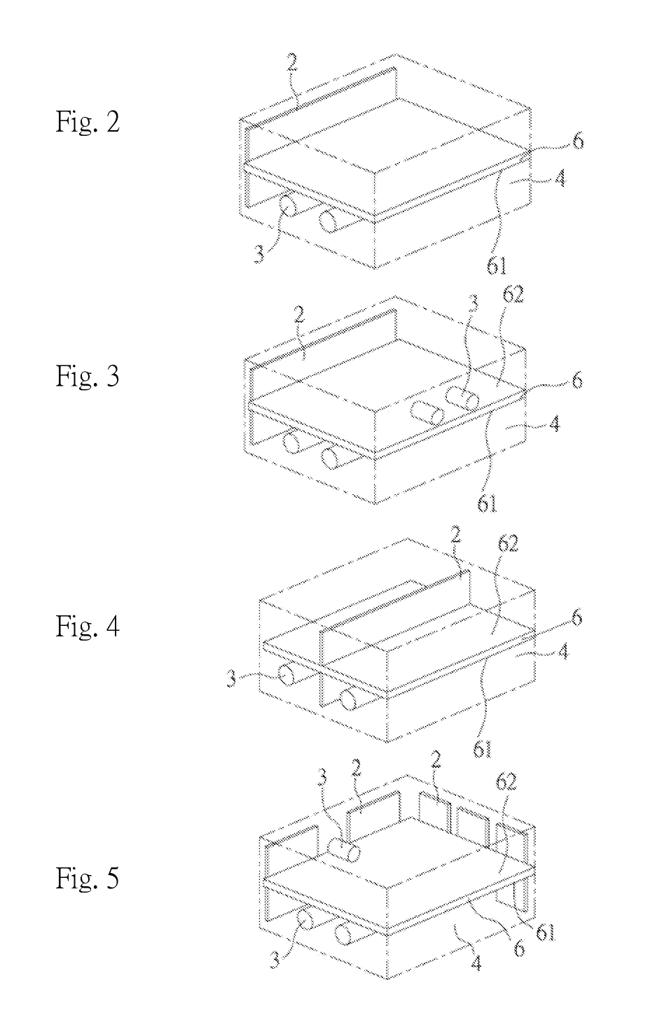

Refer to FIG. 2 a diagram schematically showing a flexible lighting-photovoltaic composite module according to Embodiment II of the present invention. The flexible lighting-photovoltaic composite module of Embodiment II is similar to that manufactured in Embodiment I except Embodiment II is free of the pattern layer and embeds the scattering layer 6 in the flexible light guide element 4. In Embodiment II, the LED light sources 3 are disposed on a first surface 61 of the scattering layer 6.

### Embodiment III

Refer to FIG. 3 a diagram schematically showing a flexible lighting-photovoltaic composite module according to Embodiment III of the present invention. The flexible lighting-photovoltaic composite module of Embodiment III is similar to that of Embodiment II except Embodiment III has additional LED light sources 3 disposed on a second surface 62 of the scattering layer 6.

### Embodiment IV

Refer to FIG. 4 a diagram schematically showing a flexible lighting-photovoltaic composite module according to Embodiment IV of the present invention. The flexible lighting-photovoltaic composite module of Embodiment IV is similar to that of Embodiment II except the photovoltaic module is embedded in the flexible light guide element 4 and penetrates the scattering layer 6 in Embodiment IV.

### Embodiment V

Refer to FIG. 5 a diagram schematically showing a flexible lighting-photovoltaic composite module according to Embodiment V of the present invention. The flexible lighting-photovoltaic composite module of Embodiment V is similar to that of Embodiment II except the LED light sources 3 are respectively disposed on the first surface 61 and second surface 62 of the scattering layer 6 and the photovoltaic cells are respectively distributed on two perpendicular sides of the flexible light guide element 4.

### Embodiment VI

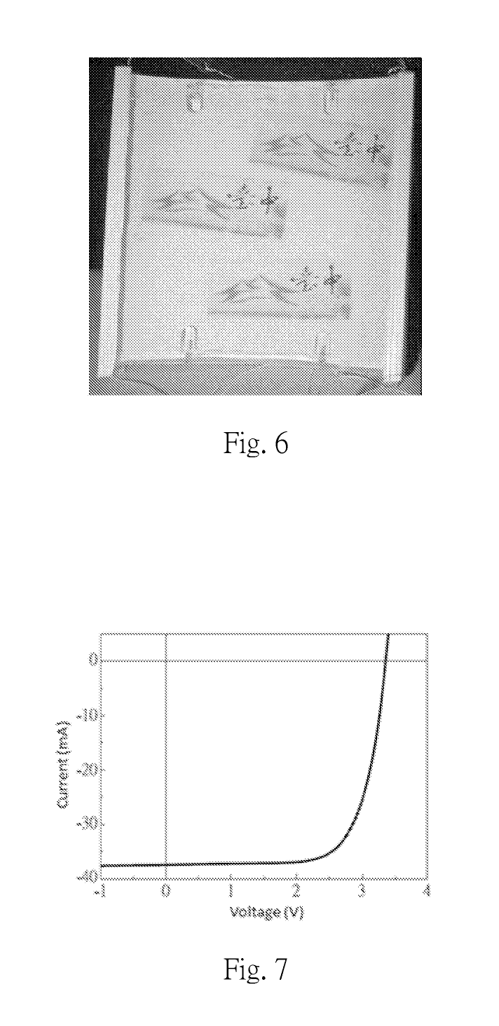

Refer to FIG. 6 a 10×10 cm2 flexible lighting-photovoltaic composite module fabricated according to Embodiment I as a sample, wherein the pattern layer is fabricated with dyes. The flexible lighting-photovoltaic composite module is connected with a battery to form an energy circulation system. The energy circulation system is further connected with an electric fan and illuminated by a 150 W halogen lamp having a luminance of about 120,000 LX. The voltage-current relationship is measured and shown in FIG. 7, having an open-circuit voltage of as high as 3.38V, a short-circuit current of 37.37 mA and a fill factor of 0.71. Embodiment VI shows that the power generated by the system is sufficient to drive the electric fan to rotate.

### Embodiment VII

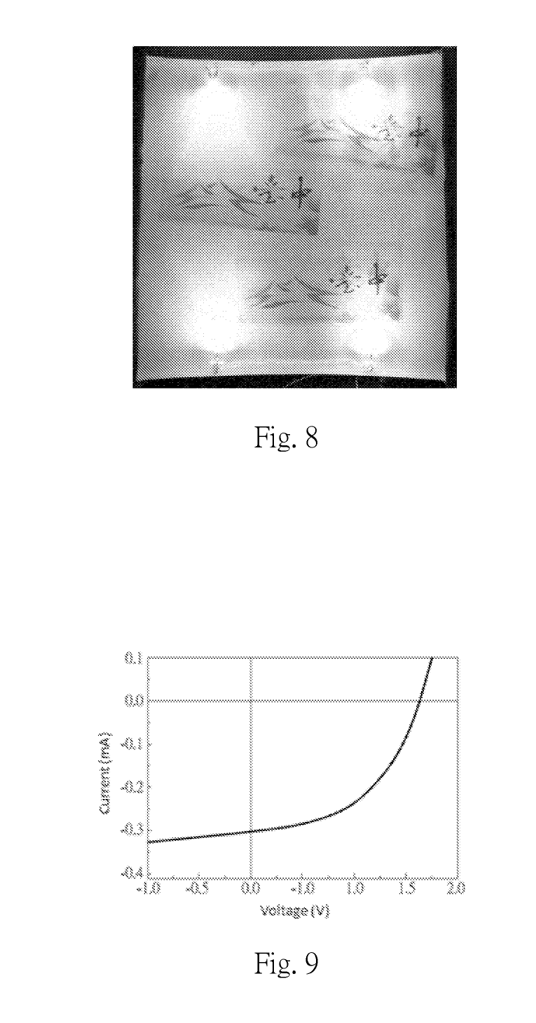

Embodiment VII is to show the energy recycling efficiency of the flexible lighting-photovoltaic composite module of the present invention. Refer to FIG. 8. Embodiment VII takes the same sample as Embodiment VI. The flexible lighting-photovoltaic composite module has 4 pieces of LEDs each having a brightness of 4000 mcd. The flexible light guide element and the scattering layer recycle a portion of the light emitted by the LEDs to the photovoltaic module. While the LEDs are emitting light, the voltage-current relationship is measured and shown in FIG. 9, having an open-circuit voltage of as high as 1.62V, a short-circuit current of 0.303 mA and a fill factor of 0.48. Embodiment VII shows that the photovoltaic cells of the flexible lighting-photovoltaic composite module can recycle the light emitted by the LEDs.

The embodiments described above are only to exemplify the present invention. The scope of the present invention is not limited by theses embodiment but is based on the claims stated below and includes modifications and variations made without departing from the spirit of the present invention.

What is claimed is:

1. A flexible lighting-photovoltaic composite module comprising:
at least one light source;
a photovoltaic module electrically connected with said light source and including at least one photovoltaic cell; and
a flexible light guide element, wherein said light source and said photovoltaic module are independently embedded in said flexible light guide element, or independently disposed on at least one side of said flexible light guide element, or independently embedded in said flexible light guide element and disposed on at least one side of said flexible light guide element to form said flexible lighting-photovoltaic composite module.

2. The flexible lighting-photovoltaic composite module according to claim 1, further comprising a scattering layer disposed on at least one side of said flexible light guide element or embedded in said flexible light guide element.

3. The flexible lighting-photovoltaic composite module according to claim 2, wherein said scattering layer is disposed on one side of said flexible light guide element; said light source is embedded in said flexible light guide element and disposed on a first surface of said scattering layer; and said photovoltaic module is disposed on at least one side of said flexible light guide element.

4. The flexible lighting-photovoltaic composite module according to claim 3, wherein said scattering layer is embedded in said flexible light guide element.

5. The flexible lighting-photovoltaic composite module according to claim 4, wherein said light source is further disposed on a second surface of said scattering layer.

6. The flexible lighting-photovoltaic composite module according to claim 4, wherein said photovoltaic module comprises a plurality of said photovoltaic cells respectively disposed at least two sides of said flexible light guide element.

7. The flexible lighting-photovoltaic composite module according to claim 3, wherein said photovoltaic module is embedded in said flexible light guide element.

8. The flexible lighting-photovoltaic composite module according to claim 7, wherein said photovoltaic module further penetrates said scattering layer.

9. The flexible lighting-photovoltaic composite module according to claim 2, further comprising a pattern layer embedded in said flexible light guide element.

10. The flexible lighting-photovoltaic composite module according to claim 9, wherein said pattern layer includes a luminescent dye.

11. The flexible lighting-photovoltaic composite module according to claim 9, further comprising a battery electrically connected to said photovoltaic module.

12. The flexible lighting-photovoltaic composite module according to claim 2, further comprising a battery electrically connected to said photovoltaic module.

13. The flexible lighting-photovoltaic composite module according to claim 1, further comprising a battery electrically connected to said photovoltaic module.

14. The flexible lighting-photovoltaic composite module according to claim 1, wherein at least one surface of said flexible light guide element includes a microstructure, which includes micro cones, micro semispheres, micro cuboids, or a combination thereof.

15. The flexible lighting-photovoltaic composite module according to claim 1, further comprising a protection layer covering surfaces of said flexible light guide element.

16. The flexible lighting-photovoltaic composite module according to claim 15, wherein said protection layer is made of a material selected from a group consisting of ETFE (ethylene-tetra-fluoro-ethylene), ECTFE (ethylene-chlorotrifluororthylene), PTFE (polytetrafluoroethylene), FEP (fluorinated ethylene propylene), PET (polyethylene terephthalate), and PC (Polycarbonate).

17. The flexible lighting-photovoltaic composite module according to claim 1, wherein said flexible light guide element is made of a light guide material selected from a group consisting of PVA (polyvinyl alcohol), PVP (poly(vinylpyrrolidinone), and PDMS (polydimethylsiloxane).

18. The flexible lighting-photovoltaic composite module according to claim 1, wherein said flexible light guide element is made of PDMS (polydimethylsiloxane).

19. A method for manufacturing a flexible lighting-photovoltaic composite module, comprising
Step (a): electrically connecting at least one light source and a photovoltaic module and securing them in a mold, wherein said photovoltaic module includes at least one photovoltaic cell;
Step (b): pouring a light guide material solution into said mold and curing said light guide material solution to form a flexible light guide element, wherein said light source and said photovoltaic module are independently embedded in said flexible light guide element, or independently disposed on at least one side of said flexible light guide element, or independently embedded in said flexible light guide element and disposed on at least one side of said flexible light guide element; and
Step (c): removing said mold to obtain a flexible lighting-photovoltaic composite module.

20. The method for manufacturing a flexible lighting-photovoltaic composite module according to claim 19, wherein said Step (b) is followed by Step (31):
embedding a pattern layer in said flexible light guide element.

21. The method for manufacturing a flexible lighting-photovoltaic composite module according to claim 20, wherein Step (b1) is followed by Step (b2):
forming a scattering layer on at least one side of said flexible light guide element.

22. The method for manufacturing a flexible lighting-photovoltaic composite module according to claim 21, wherein Step (b2) is followed by Step (b3):
pouring said light guide material solution on said scattering layer to embed said scattering layer in said flexible light guide element.

23. The method for manufacturing a flexible lighting-photovoltaic composite module according to claim 19, wherein said light guide material solution contains a light guide material and a curing agent mixed by a ratio of 10:1 to 1:1.
